(19) United States
(12) Patent Application Publication
(10) Pub. No.: US 2015/0144807 A1
(43) Pub. Date: May 28, 2015

(54) DRAWING DATA CREATING METHOD, DRAWING APPARATUS, DRAWING METHOD, AND ARTICLE MANUFACTURING METHOD

(71) Applicant: CANON KABUSHIKI KAISHA, Tokyo (JP)

(72) Inventors: Satoru Oishi, Utsunomiya-shi (JP); Hideki Ina, Tokyo (JP)

(21) Appl. No.: 14/552,438

(22) Filed: Nov. 24, 2014

(30) Foreign Application Priority Data
Nov. 28, 2013 (JP) 2013-245898
Jul. 16, 2014 (JP) 2014-146008

(51) Int. Cl. H01J 37/302; H01J 37/244; H01J 37/317

(52) U.S. Cl. CPC H01J 37/3023; H01J 37/3174; H01J 37/244; H01J 2237/31762
USPC 250/492.22

(57) ABSTRACT

The present invention relates to a method for drawing data that indicates a timing at which a substrate is irradiated with a beam. The method includes determining whether or not a mark to be irradiated with the beam exists in a predetermined region on a substrate. The method further includes creating, in a case where the mark exists in the predetermined region, the drawing data such that a mark region including the mark is irradiated with the beam at a predetermined timing after a region other than the mark region is irradiated with the beam.

### BACKGROUND OF THE INVENTION

1. Field of the Invention

The present invention relates to a drawing data creating method, a drawing apparatus, a drawing method, and an article manufacturing method.

2. Description of the Related Art

In a lithography step for manufacturing a semiconductor device, an (n+1)-th layer pattern has to be overlaid on an n-th layer pattern at a satisfactory precision. In view of the above, an alignment process based on a global alignment system is performed before a new layer pattern is formed. The global alignment system is a system in which a plurality of alignment marks for alignment formed on a substrate are detected, and a position of a new layer pattern is determined on the basis of the positions of the alignment marks.

However, in a case where an input heat value with respect to the substrate is high while the pattern is formed and thermal deformation of the substrate progresses during the formation of the pattern, the overlay precision tends to be decreased. To suppress the decrease in the overlay precision, U.S. Pat. No. 7,897,942 discloses a technology of measuring a position of an alignment mark even while a pattern on one layer is drawn and correcting a position on a substrate which is irradiated with an electron beam on the basis of the measurement result.

In a case where negative resist is applied on a substrate and also an alignment mark is to be remained or a case where positive resist is used and also an alignment mark is to be removed, the alignment mark may be irradiated with a beam. However, in a case where the alignment mark is irradiated with the beam and also position measurement of the same alignment mark is performed again after the beam irradiation, an accuracy of the position measurement may be decreased.

For example, even when a signal intensity pattern as illustrated in FIG. 14A is obtained before the beam irradiation, if optical characteristics of the resist are changed by the beam irradiation, the signal intensity may be decreased as illustrated in FIG. 14B. Accordingly, the measurement accuracy of the alignment mark may be decreased.

### SUMMARY OF THE INVENTION

According to one aspect of the invention, there is provided a method for drawing data that indicates a timing at which a substrate is irradiated with a beam, the method including: determining whether or not a mark to be irradiated with the beam exists in a predetermined region on the substrate; and creating, in a case where the mark exists in the predetermined region, the drawing data such that a mark region including the mark is irradiated with the beam at a predetermined timing after a region other than the mark region is irradiated with the beam.

Further features of the present invention will become apparent from the following description of exemplary embodiments with reference to the attached drawings.

### BRIEF DESCRIPTION OF THE DRAWINGS

FIG. 1 is a block diagram of a drawing apparatus according to a first exemplary embodiment.

FIG. 2 is an explanatory diagram for describing a drawing method.

FIGS. 3A to 3E are explanatory diagrams for describing an alignment mark.

FIG. 4 is an explanatory diagram for describing a drawing method by the drawing apparatus according to the first exemplary embodiment.

FIG. 5 is a flow chart illustrating a pattern data creating method according to the first exemplary embodiment.

FIG. 6 is an explanatory diagram for describing a mark region according to the first exemplary embodiment.

FIG. 7 is a flow chart for describing the drawing method according to the first exemplary embodiment.

FIG. 8 is an explanatory diagram for describing a drawing method by a drawing apparatus according to a second exemplary embodiment.

FIG. 9 is a flow chart for describing a drawing method according to a second exemplary embodiment.

FIG. 10 is an explanatory diagram for describing a mark region according to a third exemplary embodiment.

FIGS. 11A and 11B are explanatory diagrams for describing a drawing method according to a fourth exemplary embodiment.

FIGS. 12A and 12B are explanatory diagrams for describing a drawing method in accordance with an arrangement of a column and an alignment detection system.

FIGS. 13A and 13B illustrate an example application step of the present invention.

FIGS. 14A and 14B are explanatory diagrams for describing issues addressed by the present invention.

### DESCRIPTION OF THE EMBODIMENTS

First, descriptions will be given of an apparatus configuration of a drawing apparatus common to respective exemplary embodiments, a drawing method, and global alignment measurement. A drawing apparatus configured to draw a pattern on a wafer (substrate) by using an electron beam (beam) according to the respective exemplary embodiments will be described as an example, but the present invention can also be applied to a drawing apparatus configured to perform pattern formation by using a focused laser beam or an ion beam as the beam. In particular, the present invention is used in a case where input heat to the wafer is increased by beam irradiation.

### Apparatus Configuration

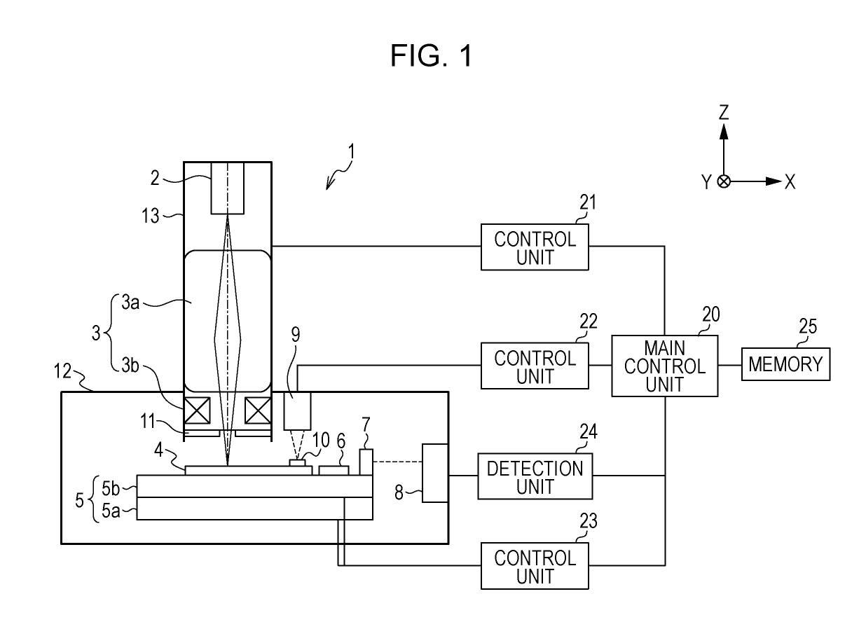

FIG. 1 is a block diagram of a drawing apparatus 1 common to the respective exemplary embodiments. A surface of a wafer 4 is irradiated with an electron beam emitted from electron gun 2 via an electron optical system 3. The electron optical system 3 includes an electron lens 3a for focusing the electron beam and a deflector 3b that deflects the electron beam. A control unit 21 controls turning ON and OFF of the electron gun 2 and also controls the electron optical system 3 to adjust a focusing position and a deflection amount of the electron beam.

A stage 5 is constituted by a Y stage 5a, an X stage 5b placed on the Y stage 5a, and a Z stage (not illustrated). The wafer 4 is supported by a wafer chuck (not illustrated) on the stage 5. The X stage 5b is moved in an X-axis direction, the Y stage 5a is moved in a Y-axis direction, and the Z stage is moved in a Z-axis direction in response to an instruction from a control unit 23 configured to control the stage 5. In addition to the wafer 4, a reference plate 6 on which a reference mark is formed, and a movable mirror 7 for the X axis are provided on the X stage 5b. The reference mark is a mark for measuring a distance between optical axes of an alignment detection system (a position measurement device) 9 which will be described below and the electron optical system 3.

An interferometer 8 splits the laser beam into measurement light and reference light and inputs the measurement light to the movable mirror 7 for the X axis and inputs the reference light to a reference mirror (not illustrated) provided inside the interferometer 8.

The lights reflected by the respective mirrors are interfered with each other, and an intensity of the interference light is detected by a detection unit 24 to detect a position of the movable mirror 7 for the X axis while the reference mirror is used as the reference, that is, a position in the X-axis direction of the stage 5. By using a similar technique, a movable mirror (not illustrated) for the Y axis which is provided on the Y stage 5a is used to detect a position in the Y-axis direction of the stage 5. The detection unit 24 transmits a measurement value to a main control unit 20, and the control unit 23 connected to the main control unit 20 controls the position of the stage 5 on the basis of the measurement value.

Resist (not illustrated) is applied to the wafer 4. A position of an alignment mark (mark) 10 (hereinafter, referred to as mark 10) formed on the wafer 4 is measured by using the alignment detection system 9 functioning as a position measurement device and a control unit 22.

The alignment detection system 9 irradiates the reference mark on the reference plate 6 or the plurality of marks 10 formed on the wafer 4 with light having a wavelength band at which the resist is not sensitized, and detects the reference mark or the mark 10. The control unit 22 processes an image of a mark captured by a sensor of the alignment detection system 9 to obtain the positional data of the mark 10. Alternatively, an intensity of diffracted light from the mark 10 is detected, and the positional data of the mark 10 is obtained from an intensity change of the detection signal.

A focus sensor 11 is configured to measure a height in the Z-axis direction of the wafer 4. The focus sensor 11 is a sensor that can be used in a vacuum chamber, such as an optical sensor or an electrostatic capacitance sensor. Devices related to the irradiation and measurement devices such as the electron gun 2, the electron optical system 3, the stage 5, the interferometer 8, and the focus sensor 11 are arranged in a vacuum chamber 12. A vacuum pump (not illustrated) performs evacuation to achieve the vacuum condition in the vacuum chamber 12.

The main control unit (control unit) 20 is connected to the control unit 21 that controls the electron gun 2 and the electron optical system 3, the control unit 22 that controls the alignment detection system 9, the control unit 23 that controls driving of the stage 5, the detection unit 24 that detects the measurement result of the interferometer 8, and a memory 25.

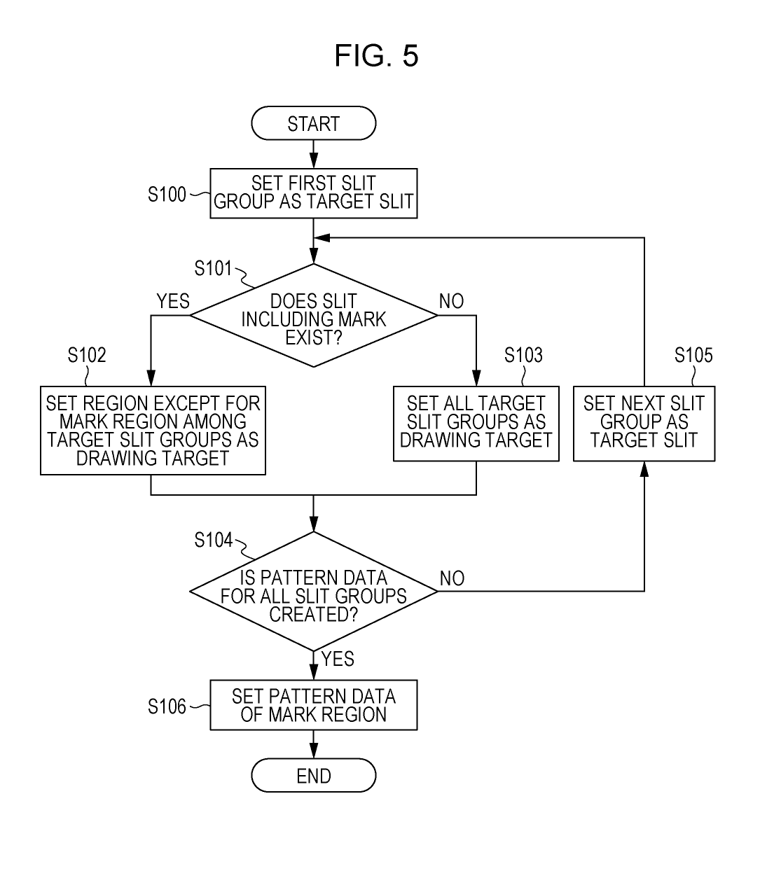

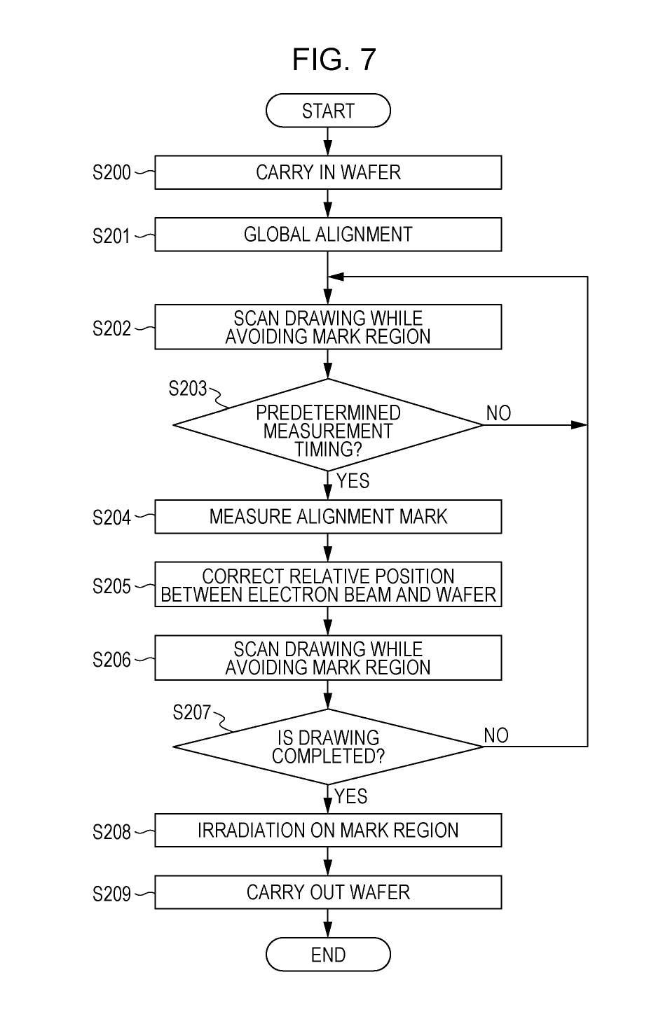

A CPU of the main control unit 20 executes programs stored in the memory 25 which have processing contents illustrated in the flow charts of FIG. 5 and FIG. 7. That is, prior to the drawing, a step of creating pattern data (drawing data) that indicates a timing at which the wafer 4 is irradiated with the electron beam and a step of irradiating the wafer 4 with the electron beam by using the created pattern data and drawing the pattern are executed. The main control unit 20 executes these programs and also controls the control units 21 to 23 and the detection unit 24. A latent image pattern is formed on the wafer 4 by controlling the irradiation position of the electron beam with respect to the wafer 4 and the position of the stage 5. The main control unit 20 also stores various measurement values in the memory 25 and executes computation based on these measurement values.

The control unit according to the exemplary embodiment of the present invention has at least a function of controlling the irradiation position of the beam with respect to the wafer 4 and the timing of the irradiation of this beam (controlling the irradiation) on the basis of the position measurement value of the mark 10. Therefore, according to the present exemplary embodiment, this control unit corresponds to the main control unit 20, the control units 21 to 23, and the detection unit 24. The memory 25 stores the programs having the processing contents illustrated in the flow charts of FIG. 5 and FIG. 7 which will be described below, data of the drawing pattern, and the created pattern data. Furthermore, the position measurement value of the mark 10 detected by the alignment detection system 9 is stored.

The data of the drawing pattern indicates data of pattern desired by the user to be drawn on the wafer 4. The data of the drawing pattern is CAD data or data in a bitmap format. The pattern data indicates data that is created on the basis of the data of the drawing pattern and indicates the timing at which the wafer 4 is irradiated with the electron beam. For example, the pattern data is control data that indicates an instruction of irradiation or non-irradiation with respect to the time axis.

FIG. 1 illustrates a state in which the wafer 4 is irradiated with the single electron beam, but the wafer 4 may be irradiated with a plurality of electron beams from a single column 13 including the electron gun 2 and the electron optical system 3. It is possible to improve the throughput by performing drawing by using the plurality of electron beams. The number of the columns 13 and the number of the alignment detection systems 9 are varied according to the respective exemplary embodiments.

### Basic Drawing Method

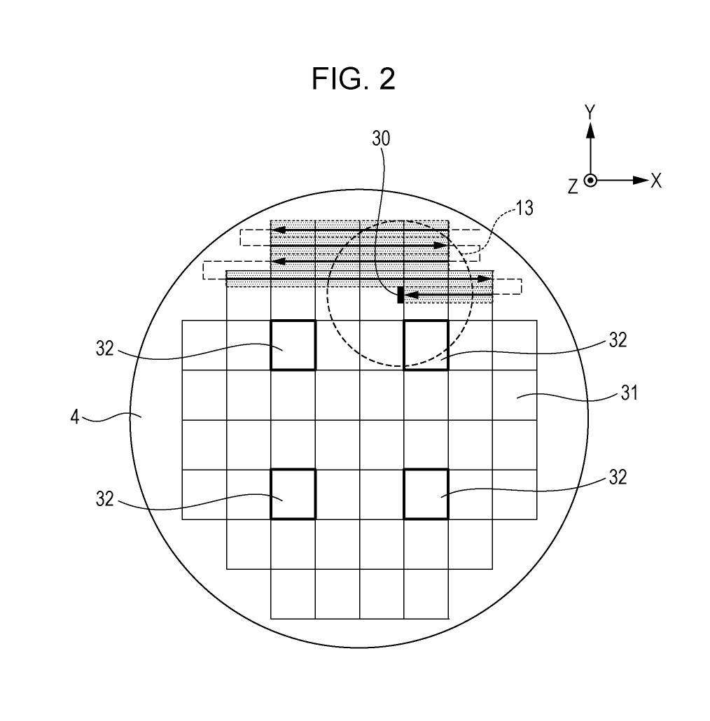

FIG. 2 illustrates a state in which the wafer 4 is irradiated with the electron beam from the single column 13. A central portion of the column 13 represents a slit-shaped irradiation region (unit irradiation region) 30. The drawing apparatus 1 irradiates the wafer 4 with the plurality of electron beams that have passed through the irradiation region 30 at once at a maximum. A width in the Y-axis direction of the irradiation region 30 is, for example, 50 to 100 μm. The pattern is drawn on the wafer 4 by reciprocating the wafer 4 in the X-axis direction and the Y-axis direction.

A solid line arrow illustrates a situation of scan drawing in which the irradiation with the electron beam is performed while the irradiation region 30 is scanned on the substrate, and a broken line illustrates a situation of step movement in which the wafer 4 is moved without being irradiated with the electron beam. Step and scan operation in which these processes are combined with each other is repeatedly performed. The main control unit 20 also appropriately causes the deflector 3b to deflect the electron beam to control the irradiation position of the electron beam with respect to the wafer 4, so that the desired pattern is drawn on the wafer 4.

### Regarding Global Alignment Measurement

The marks 10 for the global alignment measurement are formed in the vicinities of respective shot regions 31. The position of the mark 10 in the vicinity of a sample shot region 32 (hereinafter, referred to as shot region 32) which is set through the selection by the user among the respective shot regions 31, and the control unit 22 determines a position of a newly formed layer.

The shot region 32 may be located at a position where a position measurement error derived from the process hardly occurs, and the shot region 32 is therefore set while avoiding an outermost circumference of the wafer where a distortion is likely to occur in steps other than an exposure step. To detect a magnification deformation at a satisfactory accuracy, the positions of the shot regions 32 may be set to be away from each other as much as possible. As the number of measurement points is increased, the alignment precision is increased. However, suppression of a decrease in the throughput caused by too many position measurements of the mark 10 is also taken into account. FIG. 2 illustrates an example arrangement mode of the shot region 32.

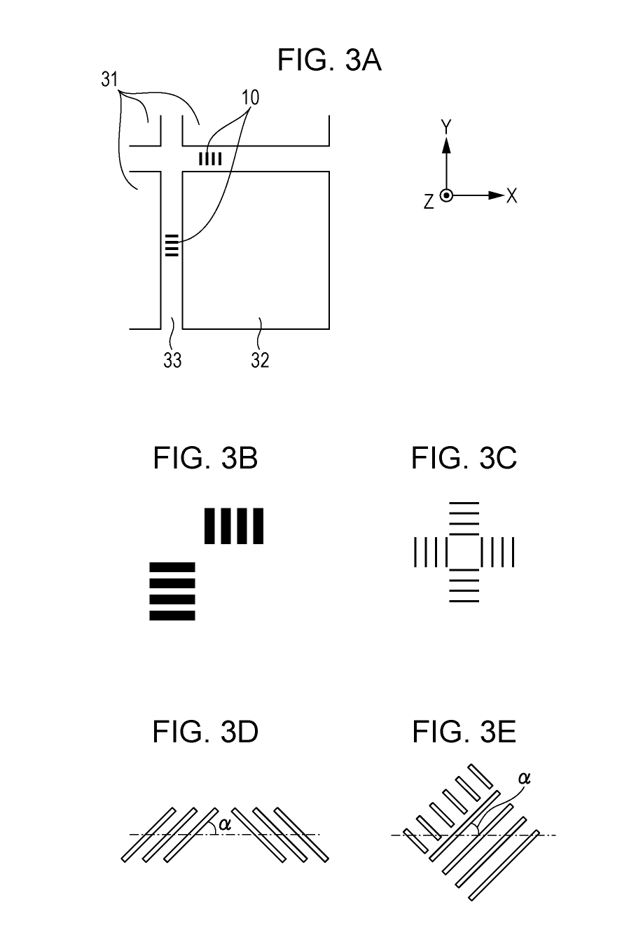

FIGS. 3A to 3E are explanatory diagrams for describing the global alignment measurement. FIG. 3A is an expanded view of a region surrounding the shot region 32 illustrated in FIG. 2. A scribe line 33 having a width of approximately 80 to 100 μm is located between the shot regions 31 corresponding to the drawing target. As illustrated in FIG. 3A, the mark 10 having a width of approximate 40 to 60 μm in the X-axis direction is formed so as to be contained within the scribe line 33.

The mark 10 includes types illustrated in FIGS. 3B to 3E, and the mark shape to be used is varied in accordance with the measurement method.

In the case of the system where the alignment detection system 9 focuses the reflected light from the mark 10 onto the sensor in a state in which the stage 5 remains stationary, marks illustrated in FIGS. 3B and 3C are used. In particular, advantages may be attained that the positions in the X-axis direction and the Y-axis direction can be measured at once by using the mark shape of FIG. 3C, and also driving of the stage 5 is avoided.

On the other hand, a method of detecting an intensity of the diffracted light from the mark 10 and measuring the position from the intensity change of the detection signal is also conceivable. According to this method, the measurement can be performed even in a state in which the stage 5 is scanned. For example, the alignment detection system 9 may include a time delay integration (TDI) sensor.

In this case, mark shapes of FIGS. 3D and 3E are used. Since straight lines constituting the mark 10 form a shape to be inclined at an angle α with respect to a direction in which the alignment detection system 9 scans, the positions in the X-axis direction and the Y-axis direction can be obtained at the same during the scan drawing. An advantage may be attained that the decrease in the throughput can be suppressed since it is possible to perform the position measurement of the mark 10 without stopping the stage 5.

Subsequently, a determination method for the overlay position on the basis of the position measurement result of the mark 10 will be described. The main control unit 20 performs statistical processing on the basis of the position information of the stage 5 measured by using the interferometer 8 and the position measurement result of the mark 10 in the shot region 32 and determines a lattice arrangement of patterns formed on determines the wafer 4.

Position coordinates (x′, y′) of the shot region 31 after the correction are represented as Expression (1) by using position coordinates (x, y) of the shot region 31 before the correction, and the main control unit 20 draws the pattern at the position coordinates (x′, y′) after the correction obtained by Expression (1). It is noted that shift components of the lattice arrangement are set as Sₓ and S_{y}, magnification component are set as mₓ and m_{y}, and rotation components are set as θₓ and θ_{y} which are obtained from the measurement values of the plurality of alignment marks.

$$( \begin{matrix}{x}^{′} \\ {y}^{′}\end{matrix} ) = ( \begin{matrix}Sx \\ Sy\end{matrix} ) + ( \begin{matrix}mx cos θ x & - my sin θ y \\ mx sin θ x & my cos θ y\end{matrix} ) ( \begin{matrix}x \\ y\end{matrix} ) \qquad ( 1 )$$

### First Exemplary Embodiment

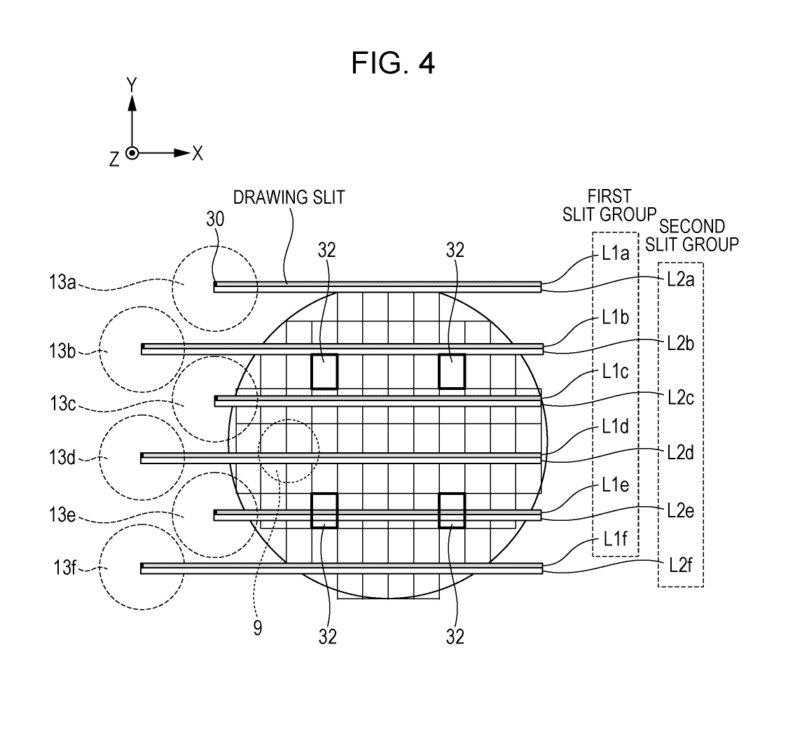

The drawing apparatus 1 according to a first exemplary embodiment has a configuration in which the six columns 13 and the single alignment detection system 9 are integrated with each other as illustrated in FIG. 4.

The wafer 4 scans once with respect to the irradiation regions 30 of the columns 13a to 13f in the X-axis direction (one direction) in FIG. 4, and a strip pattern is drawn. A region for this single scan drawing will be hereinafter referred to as slit (predetermined region). A slit drawn first by the column 13a is set as a slit L1a, and a slit drawn next is set as a slit L2a. Similarly, slits drawn first by the column 13b to 13f are set as slits L1b to L1f. The slits drawn first by the columns 13a to 13f are referred to as first slit group (L1a to L1f).

Hereinafter, similarly, slits drawn by the m-th time are referred to as m-th slit group. If a diameter of the wafer 4 is set as 300 mm, a width of the irradiation region 30 is set as 100 μm, and an interval between the columns is set as 50 mm, the drawing apparatus 1 completes the drawing in the region of the drawing target on the wafer 4 at the time of m=500.

The main control unit 20 creates the pattern data on the basis of the data of the desired drawing pattern stored in the memory 25. According to the present exemplary embodiment, the main control unit 20 creates the pattern data in units of the slit group. A creation procedure for the pattern data will be described by using a flow chart illustrated in FIG. 5. These processings are performed when the main control unit 20 executes the programs stored in the memory 25.

Before the flow chart illustrated FIG. 5 is started, the main control unit 20 is assumed to obtain the data of the drawing pattern, the layout of the shot regions 31, the position of the already formed mark 10, and information related to the size of the region at least including the mark 10 (hereinafter, referred to as mark region 35). That is, this is a state in which the arrangement of the patterns to be formed on the wafer 4 has been already determined.

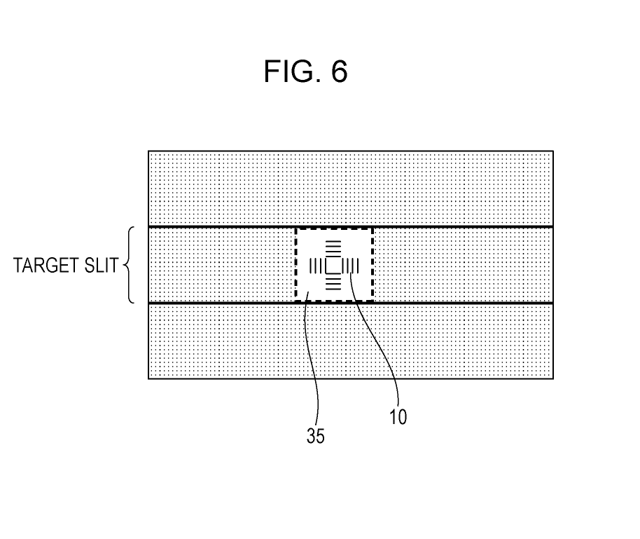

In S100, the main control unit 20 sets the first slit group as the target slit for the pattern data creation. In S101, the main control unit 20 determines whether or not the mark 10 exists in the slit group set as the target slit (whether or not the mark to be irradiated with the beam exists). In S101, in a case where the main control unit 20 determines that the slit including the mark 10 exists (YES), the pattern data is created while a region other than the mark region 35 is set as the drawing target. FIG. 6 illustrates an example of the mark region 35. The mark region 35 has a rectangular shape that surrounds the mark 10. In S101, in a case where the main control unit 20 determines that the mark 10 does not exist (NO), the region to be drawn in all the slits in the target slit group is set as the drawing target to create the pattern data (S103).

When the creation of the pattern data of the target slit group is completed, in S104, it is determined whether or not the pattern data for all the slit groups (m=1 to 500 according to the present exemplary embodiment) is created. When it is determined that pattern data that has not yet been created exists (NO), the slit group corresponding to the next drawing target is set as the target slit (S105), and the operation in S101 to S104 is repeatedly performed.

In S104, when it is determined that the pattern data of all the slit groups is created (YES), the pattern data to be irradiated lastly is set (S106). That is, the pattern created in S106 is a pattern for performing irradiation on all the mark regions 35 that are not set as the target in the processing in S102. In this manner, the pattern data is created in which the irradiation timing is set such that the mark region is irradiated with the electron beam at the predetermined timing after the region other than the mark region is irradiated with the electron beam.

Next, a step of drawing a pattern on the basis of the created pattern data will be described by using a flow chart illustrated in FIG. 7. In S200, the main control unit 20 instructs a wafer conveyance mechanism (not illustrated) to carry in the wafer 4 to the column 13. In S201, the global alignment measurement is executed. That is, the alignment detection system 9 detects the mark 10 formed in the vicinity of the shot region 32, and a lattice arrangement of the patterns to be drawn is determined by using the measurement result and Expression (1) described above.

In S202, the scan drawing is sequentially performed from the first slit group on the basis of the pattern data created in the step illustrated in FIG. 5. That is, in a case where the mark 10 is increased in the slit of the drawing target, the region other than the mark region 35 out of the first slit group is irradiated with the electron beam.

In S203, the main control unit 20 determines whether or not this is a predetermined measurement timing at which the alignment detection system 9 detects the mark 10. The predetermined measurement timing is a previously set timing and may be every n slits, every certain times, or the like, in a case where densities of the patterns to be drawn are relatively uniform across all the shot regions 31. On the other hand, in a case where a difference in the densities of the patterns to be drawn is large, the predetermined measurement timing may be set as a timing at which the total irradiation amount reaches a certain value.

In a case where the main control unit 20 determines that this is not the measurement timing in S203 (NO), the scan drawing is continuously performed. In a case where the main control unit 20 determines that this is the predetermined measurement timing (YES), the drawing is interrupted once. Subsequently, after the wafer 4 is moved, the alignment detection system 9 measures the mark 10 (S204).

The main control unit 20 corrects a relative position between the irradiation position of the electron beam and the wafer 4 on the basis of the measurement result in S204 (S205). Specifically, the deformation amount of the wafer 4 which is obtained from a difference between the position measurement values of the mark 10 measured at the different timings in S201 and S204 is obtained to perform the correction of the relative position between the irradiation position of the electron beam and the wafer 4 with respect to the irradiation region of the measurement in S204 and subsequent steps. Even in a case where the wafer 4 is subjected to the thermal deformation by correcting the relative position between the irradiation position of the electron beam and the wafer 4 also during the drawing by the instruction of the main control unit 20, it is possible to suppress the decrease in the overlay precision of the patterns.

After the displacement is corrected, the drawing is performed again while the mark region 35 is avoided (S206). While the scan drawing is performed, in S207, it is determined whether or not the drawing on the region other than the mark region 35 is completed.

In a case where the main control unit 20 determines that the drawing is not completed (NO), the drawing is continuously performed in S202, and the processing in S202 to S207 is repeatedly performed until the drawing is completed.

In S207, in a case where the main control unit 20 determines that the drawing is completed (YES), in S208, the irradiation is performed on the mark region 35 where the irradiation has not been performed at the time of the scan drawing. At the time of the irradiation on the mark region 35, the pattern of the mark 10 used for forming the next layer is drawn. After the completion of the irradiation on the mark region 35, in S209, the wafer 4 is carried out to complete this program, and the drawing processing on the next wafer 4 is performed.

According to the present exemplary embodiment, during the processing of the single wafer 4, while the scan drawing is performed by the plurality of columns 13, the alignment detection system 9 measures the position of the same mark 10 plural times. Even though the input heat value to the wafer 4 is high in the vacuum chamber 12, and also it is difficult to exhaust heat because of the vacuum system, the pattern can be drawn at a satisfactory precision by performing the position alignment plural times. Furthermore, since the drawing is performed in the above-described manner, the measurement error derived from the decrease in the signal intensity or the shift of the signal position is reduced even in a case where the position of the mark 10 is measured plural times, and it is possible to correct the relative position between the irradiation position of the electron beam and the wafer 4 at a stable accuracy.

It is noted that, after the difference between the position of the mark 10 measured in S201 and the position of the mark 10 measured in S204 is obtained, if the deformation amount is lower than or equal to a predetermined amount as a result, the correction processing of the relative position in S205 is not performed, and the scan drawing may be continued. According to this configuration, it is beneficial in terms of the throughput. The drawing of the pattern of the mark 10 in S208 may be avoided depending on a degree of the demanded overlay precision, and simply, the mark region 35 may be entirely irradiated with the electron beam.

A configuration in which the mark region 35 has the size at least surrounding the mark 10 like the present exemplary embodiment is applied to a case where the number of the mark regions 35 is low or a case where the influence of the thermal distortion of the wafer 4 is large. Since the number of areas that are sensitive about the stitching between the mark region 35 and the region surrounding the mark region 35 is low, when the drawing is lastly performed in the mark region 35, an advantage may be attained that deterioration of the stitching precision of the pattern between the mark region 35 and the other region in contact with the region 35 can be alleviated.

In a case where the timing for measuring the position of the mark 10 has been determined, the predetermined timing for irradiation for the mark region 35 with the electron beam may be before or after all the regions other than the mark region 35 are irradiated with the electron beam. The predetermined timing may be set at a timing after the region other than the mark region 35 expected to be irradiated among the region in the slit is irradiated with the electron beam, a timing after the position measurement of the mark 10 is performed a predetermined times, a timing after the last position measurement is completed, or the like, and the pattern data may be created.

Furthermore, instead of determining whether or not the slit including the mark 10 exists as in S101, it may be determined as to whether or not the mark 10 exists in the predetermined region, for example, in the region to be drawn while the position of the same mark 10 is measured again after the position of the mark 10 is measured once.

It is noted that in a case where the main control unit 20 determines that the slit including the mark 10 exist (YES) in S101, pattern data different from the above-described pattern data can also be created. For example, the pattern data may be created such that the mark region 35 is irradiated with the electron beam in lower energy than a predetermined value, and the region other than the mark region 35 out of the region in the slit is irradiated with the electron beam in higher energy than the predetermined value. The predetermined value is set, for example, as energy amount at which a change in solubility by irradiation on resist applied to the wafer 4 is 20% after conversion in terms of film thickness after development has been performed.

Accordingly, even when the region irradiated with the electron beam in lower energy than the predetermined value is developed, a change in chemical characteristics of the resist is almost the same as a change in a case where the region is not irradiated with the electron beam. For that reason, according to the present technique too, the decrease in the accuracy of the position measurement of the alignment mark can be suppressed.

### Second Exemplary Embodiment

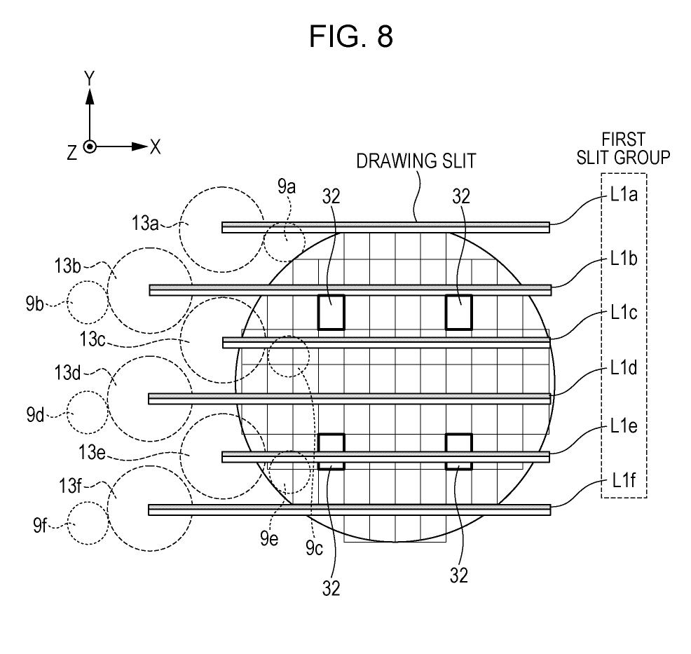

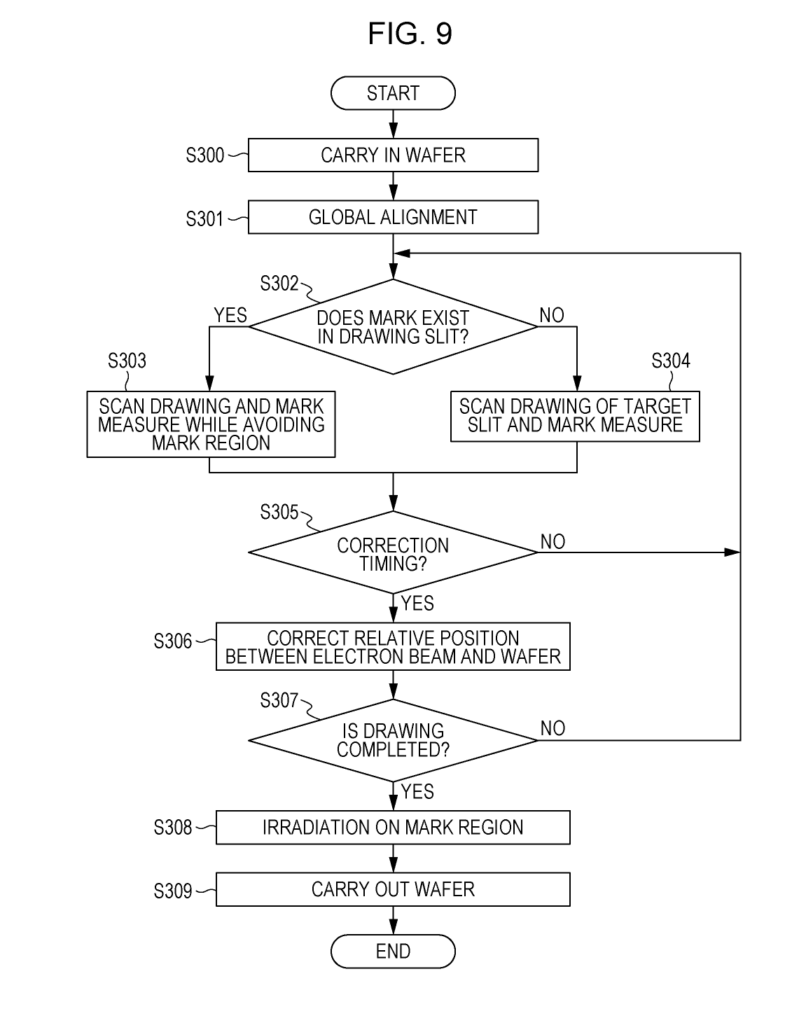

As illustrated in FIG. 8, the drawing apparatus 1 according to a second exemplary embodiment is provided with the six columns 13a to 13f and the six alignment detection systems 9a to 9f. Furthermore, a difference from the first exemplary embodiment resides in that programs illustrated in a flow chart of FIG. 9 are stored in the memory 25.

A drawing method according to the second exemplary embodiment will be described by using the flow chart of FIG. 9. The programs illustrated in the flow chart of FIG. 9 are executed while the main control unit 2 controls the control units 21 to 23 and the detection unit 24. Processings in S300 and S301 are similar to those in S200 and S201 of the flow chart of FIG. 7, and descriptions thereof will be omitted.

The pattern data can be defined in separate cases where the mark region 35 is included (YES) and where the mark region 35 is not included (NO) (S302). In a case where the mark region 35 is included (YES), in S303, the column 13 performs the scan drawing while the mark region 35 is avoided. Furthermore, in a case where the mark 10 exists in that scan range, the alignment detection system 9 appropriately measures the position of the mark 10.

On the other hand, in a case where the mark region 35 is not included (NO), the scan drawing is performed on the entire range of the slit (S304). Furthermore, in a case where the mark 10 exists in that range of the scan drawing, the alignment detection system 9 appropriately measures the position of the mark 10. For that reason, possibly, some of the marks 10 may not be measured, and all the numbers of measurements of the individual marks 10 may not be same. That is, in a case where the plurality of marks 10 including first mark and second mark exist, the predetermined number of times of the first mark may be different from the predetermined number of times of the second mark.

When the correction processing of the relative position between the electron beam and the wafer 4 is performed on the basis of the position measurement values obtained by measuring the same mark 10 plural times, the position measurement values are measured by the same alignment detection system 9 or different alignment detection systems 9.

The positions of the mark 10 measured in S303 and S304 are stored in the memory 25. In S305, the main control unit 20 determines whether or not this is a correction timing. The correction timing is a timing at which the wafer 4 is deformed by a predetermined amount or more on the basis of the position measurement values of the mark 10 accumulated in the processings in S303 and S304. Alternatively, the correction timing may be set on the basis of the determination reference similar to the above-described predetermined timing.

In a case where the main control unit 20 determines in S305 that this is the correction timing (YES), the relative position between the electron beam and the wafer 4 is corrected in accordance with the deformation amount by the thermal distortion in S306. In a case where the main control unit 20 determines that this is not the correction timing (NO), the processings in S302 to S305 are repeatedly performed.

The main control unit 20 determines whether or not the drawing on the region other than the mark region 35 is completed in S307. In a case where the main control unit 20 determines that the drawing is completed, the mark region 35 is irradiated with the electron beam while the drawing of the mark 10 is performed in S308. Finally, in S309, the wafer 4 is carried out.

Since the drawing apparatus 1 according to the present exemplary embodiment includes the plurality of alignment detection systems 9, the alignment detection system 9 can detect a plurality of the marks 10 at once. Accordingly, it is possible to shorten the time used for measuring the mark 10. In addition, since the position measurement of the mark 10 can be executed at a high frequency during the scan drawing, it is also possible to improve the correction accuracy of the drawing position.

### Third Exemplary Embodiment

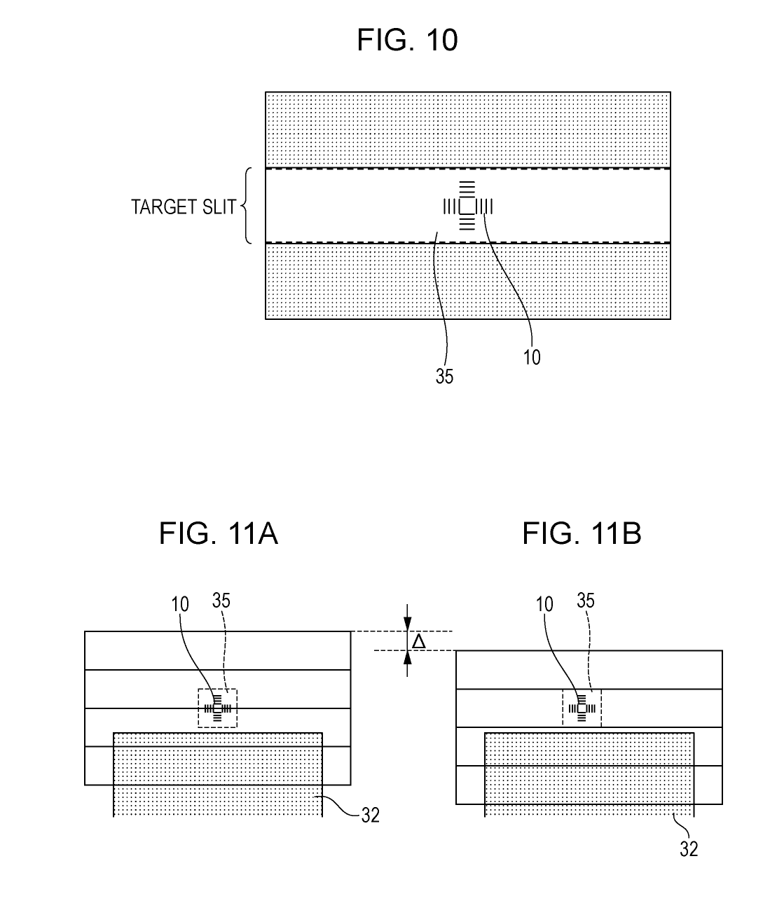

Next, a third exemplary embodiment will be described. A difference from the first and second exemplary embodiments resides in that, instead of locally setting the region surrounding the mark 10 as the mark region 35 as illustrated in FIG. 6, a single slit including the mark 10 (transition region of the unit irradiation region while the substrate is scanned in one direction with respect to the unit irradiation region of the beam) is all set as the mark region 35 as illustrated in FIG. 10.

In association with the above-described configuration, according to the present exemplary embodiment, the mark region 35 in the flow charts illustrated in FIG. 5 and FIG. 7 is also set as the single slit. That is, in a case where the mark 10 is included in the drawing target slit of the columns 13a to 13f, the pattern data with which the region other than the single slit including the mark 10 as the mark region 35 out of slit groups is irradiated is created. In S208 of the flow chart illustrated in FIG. 7, the slit corresponding to the mark region 35 is irradiated with the electron beam.

The present exemplary embodiment, where the single slit corresponding to the transition region while the irradiation region 30 is scanned once in one direction is set as the mark region 35, attains an advantage that it is sufficient that the column 13 is scanned just once on the slit where the mark region 35 exists. That is, since the column 13 does not need to be scanned on the same slit twice for the drawing in the region other than the mark region 35 and the drawing in the mark region 35 as in the first and second exemplary embodiments, the throughput is improved.

The present exemplary embodiment is more effective in a case where the number of the shot regions 32 is high, and the marks 10 indicating those positions are on the same slit. Furthermore, when the slits corresponding to the mark regions 35 are set to be the same slit group, the time used for the last irradiation on the slit corresponding to the mark region 35 can be finished only by the time in which the scan drawing is performed for one slit.

### Fourth Exemplary Embodiment

As illustrated in FIG. 11A, the mark region 35 may stride over a plurality of slits in some cases depending on the width of the slit and the size of the mark 10.

In this case, as illustrated in FIG. 11B, the slits may be wholly shifted by Δ such that the mark region 35 is contained in a single slit. Specifically, a method of creating the pattern data again to shift the position of the column 13 with respect to the wafer 4 by the main control unit 20, a method of using the deflector 3b to change the position of the slit irradiated with the electron beam without shifting the position of the column 13, and the like, may be employed.

The region where the drawing has been performed first and the mark region 35 where the drawing is performed later receive different thermal influences. For that reason, by setting the mark region 35 to be contained in the single slit as much as possible, it is possible to avoid the decrease in the stitching precision which may occur in a case where the drawing is separately performed twice.

Furthermore, it is possible to avoid creating the data to be drawn while avoiding the mark region 35, for the two slits. For that reason, an advantage may be attained that it is possible to avoid the complication of the data processing performed when the main control unit 20 creates the pattern data.

### Other Exemplary Embodiments

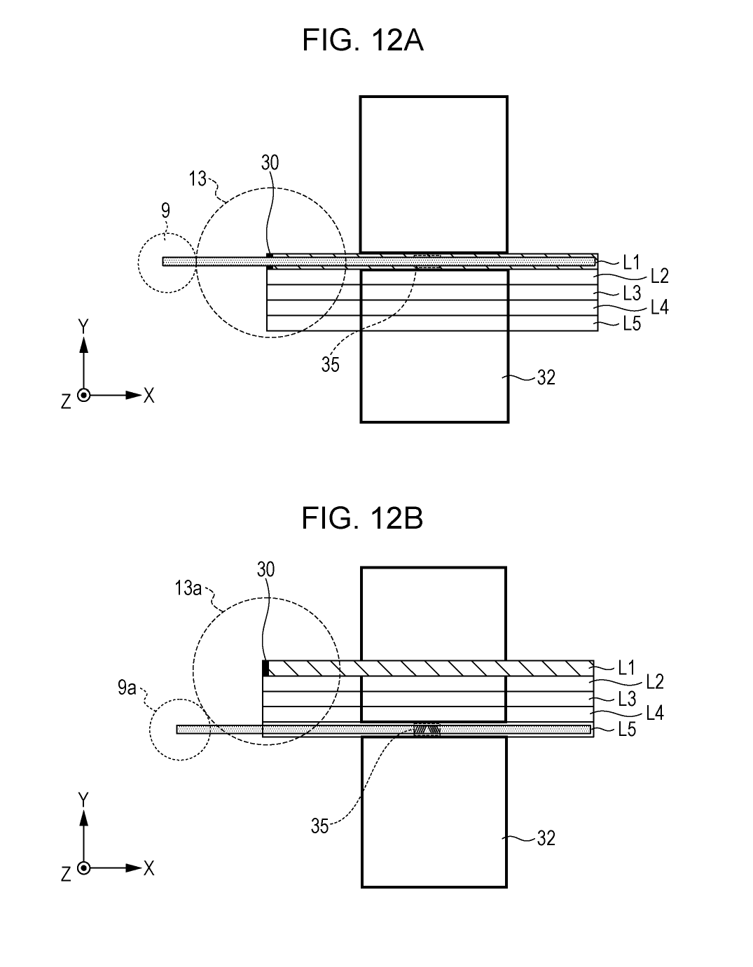

As the arrangement of the column 13 and the alignment detection system 9, for example, modes illustrated in FIGS. 12A and 12B are proposed. As illustrated in FIG. 12A, a configuration in which the column 13 and the alignment detection system 9 are arranged side by side in the scanning direction (the X-axis direction) is applied to a case where the drawing is to be performed while also taking into account the situation where the deformation caused by the heat is hardly restored, and also the amount of the thermal distortion caused by the single irradiation is high.

On the other hand, as illustrated in FIG. 12B, a configuration in which the column 13 and the alignment detection system 9 are not arranged side by side in the scanning direction may be applied to a case where the distortion caused by the heat is easily restored. This is because, by temporarily measuring the measurement position of the mark 10 that is located in the region slightly away from the position where the thermal distortion locally occurs, the drawing position can be corrected on the basis of an average deformation amount of the wafer 4.

In addition, the alignment detection system 9 used upon the drawing can be selected by configuring the arrangements of FIGS. 12A and 12B in combination. According to the first to fourth exemplary embodiments, in a case where the wafer of the same lot is processed, the measurement result of the mark 10 measured in the first wafer and the result of the displacement correction may also be applied to the other wafers. When the processings are performed in this manner, an advantage may be attained that the time used for the alignment measurement is shortened, and the load of the data processing executed by the main control unit 20 is reduced.

The mark region 35 is not limited to have the shapes illustrated in FIG. 6 and FIG. 10 but may be larger than at least the mark 10, and also the mark region 35 may be located in the region of the scribe line 33 (within the scribe line). Since the mark region 35 is not included in the shot regions 31, it is possible to lower an acceptable value of the stitching precision at a time when the irradiation on the mark region 35 is performed later.

In the case of a cluster-type drawing apparatus that includes the plurality of vacuum chambers 12 and performs the drawing processing on the plurality of wafers 4 at once, the pattern data may be collectively created by the single main control unit 20 and may also be created by the plurality of main control units 20 corresponding to the respective vacuum chambers 12.

The drawing apparatus may perform the drawing while the control units 21 to 23 and the detection unit 24 are controlled by using pattern data created at a different location even in a case where the main control unit 20 does not have the function of creating the pattern data.

In a case where the creation processing of the pattern data is fast, the pattern data may be progressively created while the drawing for several slits is performed without creating the pattern data prior to the drawing. Accordingly, it is possible to create the pattern data while the positional fluctuation of the mark 10 caused by the drawing is also taken into account.

### Applied Scenes of the Respective Exemplary Embodiments

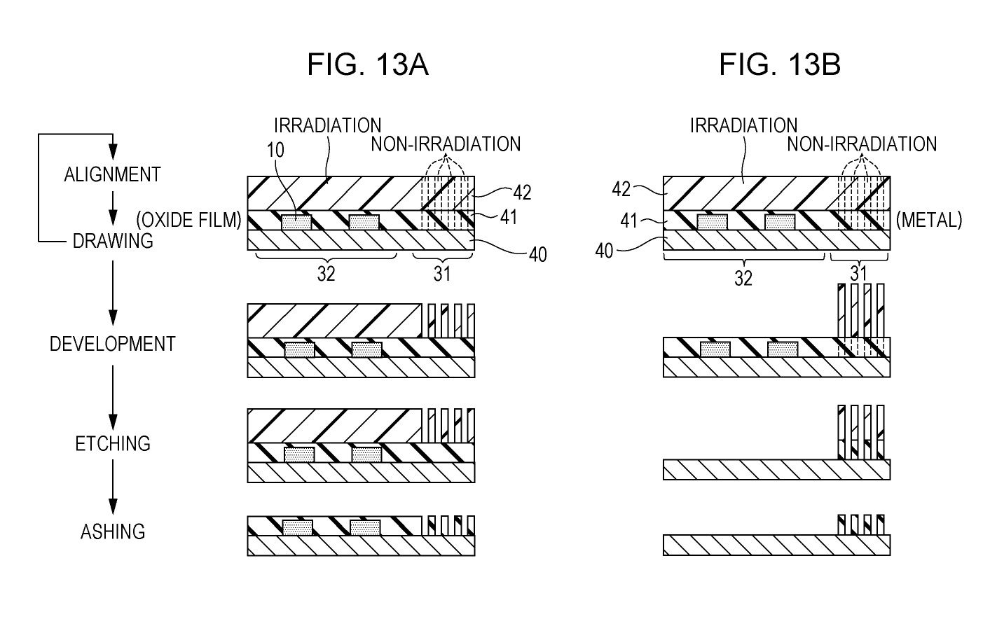

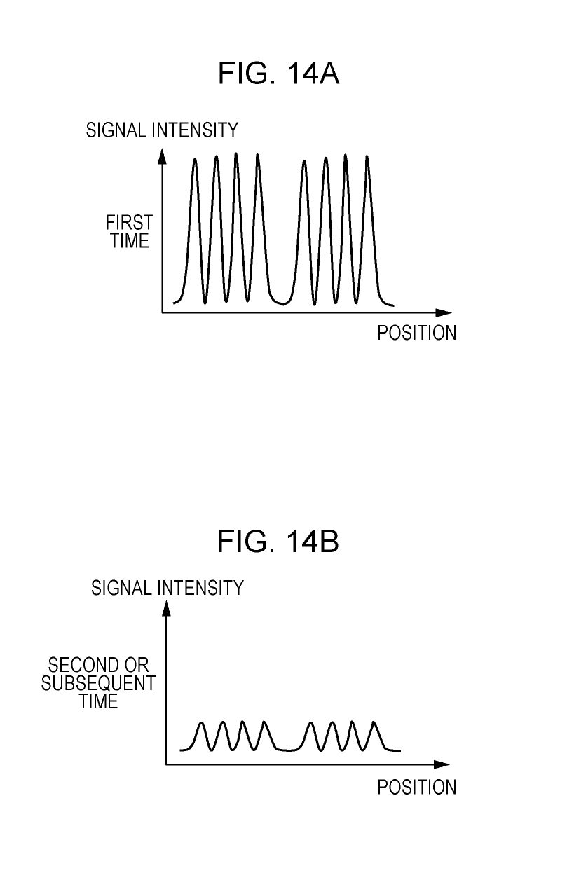

Even when the resist applied to the wafer 4 is the negative resist or the positive resist, the mark 10 may be set as the drawing target region in some cases. The above-described respective exemplary embodiments are applied to a case where the mark 10 needs to be irradiated with the electron beam and also the mark 10 is measured plural times. Since scenes to which the present invention is applied are varied in accordance with a type of the resist, example applied scenes of the present invention will be described by using FIGS. 13A and 13B.

FIGS. 13A and 13B illustrate states after the irradiation where the alignment measurement and the drawing are performed, after the development, after the etching, and after the asking, from a state in which a target layer 41 corresponding to a pattern formation target and a resist layer 42 are formed on a base layer 40 on which the pattern has already been formed.

FIG. 13A illustrates a state in which an insulating layer such as an oxide film or a nitride film is formed as the target layer 41, and negative resist is formed as the resist layer 42. The negative resist has a property in which the region irradiated with the beam remains after the development. The negative resist is applied to a case in which the pattern is formed on the target layer 41 while the mark 10 formed before the formation of the target layer 41 is left remaining by using this property.

On the other hand, FIG. 13B illustrates a state in which a metallic layer made of aluminum or tungsten as the target layer 41, and positive resist is formed as the resist layer 42. The positive resist has a property in which the region irradiated with the beam is dissolved by the development. The positive resist is applied to a case in which the pattern is formed on the target layer 41 by removing the mark 10 formed before the formation of the target layer 41 by using this property. Accordingly, it is possible to suppress the adverse effect on the characteristics of the device since the metallic layer in the region surrounding the mark 10 is peeled off while the mark 10 is left remaining, and contamination is generated.

### Article Manufacturing Method

A manufacturing method for an article (such as a semiconductor integrated circuit element, a liquid crystal display element, an image pickup element, a magnetic head, a CD-RW, an optical element, or a photo mask) according to the present invention includes drawing a pattern on a substrate (such as wafer or glass), developing the substrate on which the pattern is drawn, and performing at least one of etching processing and ion implantation processing with respect to the substrate after the development. Furthermore, the manufacturing method may also include other processing in related art (such as oxidation, film formation, vapor deposition, flattening, resist removing, dicing, bonding, or packaging).

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2013-245898, filed Nov. 28, 2013, and Japanese Patent Application No. 2014-146008, filed Jul. 16, 2014, which are hereby incorporated by reference herein in their entirety.

What is claimed is:

1. A method for drawing data that indicates a timing at which a substrate is irradiated with a beam, the method comprising:
determining whether or not a mark to be irradiated with the beam exists in a predetermined region on the substrate; and
creating, in a case where the mark exists in the predetermined region, the drawing data such that a mark region including the mark is irradiated with the beam at a predetermined timing after a region other than the mark region is irradiated with the beam.

2. A method for drawing data that indicates a timing at which a substrate is irradiated with a beam, the method comprising:
determining whether or not a mark to be irradiated with the beam exists in a predetermined region on the substrate; and
creating, in a case where the mark exists in the predetermined region, the drawing data such that the mark region including the mark is irradiated with the beam at a predetermined timing after the mark region is irradiated with a beam in lower energy than a predetermined value and also a region other than the mark region is irradiated with the beam in higher energy than the predetermined value.

3. The method for the drawing data according to claim 1, wherein the predetermined timing is a timing after position measurement with respect to the mark is completed a predetermined number of times.

4. The method for the drawing data according to claim 3, wherein, in a case where a plurality of marks including first mark and second mark exist, the predetermined number of times of the first mark is different from the predetermined number of times of the second mark.

5. The method for the drawing data according to claim 1, wherein the predetermined timing is a timing after last position measurement with respect to the mark is completed.

6. The method for the drawing data according to claim 1, wherein the mark region is within a scribe line.

7. The method for the drawing data according to claim 1, wherein the mark region is a transition region of a unit irradiation region while the substrate is scanned in one direction with respect to the unit irradiation region of the beam.

8. An apparatus that draws a pattern on a substrate with a beam, the apparatus comprising:
a position measurement device configured to measure a position of a mark formed on the substrate; and
a control unit configured to control irradiation of the substrate with the beam,
wherein, in a case where the mark exists in a predetermined region, the control unit controls the irradiation of the substrate in a manner that, at a predetermined timing after a region other than a mark region including the mark is irradiated with the beam, the mark region is irradiated with the beam.

9. An apparatus that draws a pattern on a substrate with a beam, the apparatus comprising:
a position measurement device configured to measure a position of a mark formed on the substrate; and
a control unit configured to control irradiation of the substrate with the beam,
wherein, in a case where the mark exists in a predetermined region, the control unit controls the irradiation of the substrate in a manner that, at a predetermined timing after a mark region including the mark is irradiated with a beam in lower energy than a predetermined value, and also the region other than the mark region is irradiated with the beam in higher energy than the predetermined value, the mark region is irradiated with the beam.

10. The apparatus according to claim 8,
wherein the position measurement device measures a position of the mark plural times, and
wherein the control unit corrects a position of the substrate relative to an irradiation position of the beam based on a result measured by the position measurement device.

11. The apparatus according to claim 8, further comprising a plurality of position measurement devices, wherein a position of the mark is measured plural times by the same position measurement device or different position measurement devices.

12. A method comprising:
determining whether or not a mark to be irradiated with a beam exists in a predetermined region on a substrate; and
creating, in a case where the mark exists in the predetermined region, drawing data that indicates a timing at which the substrate is irradiated with the beam in a manner that, at a predetermined timing after a region other than a mark region including the mark is irradiated with the beam, the mark region is irradiated with the beam; and
drawing a pattern on the substrate with the beam based on the drawing data.

13. An article manufacturing method comprising:
irradiating a substrate with a beam by using an apparatus;
developing the substrate; and
performing at least one of etching processing and ion implantation processing on the substrate,
wherein the apparatus comprises:
a position measurement device configured to measure a position of a mark formed on the substrate; and
a control unit configured to control irradiation of the substrate with the beam, and
wherein, in a case where the mark exists in a predetermined region, the control unit controls the irradiation of the substrate in a manner that, at a predetermined timing after a region other than a mark region including the mark is irradiated with the beam, the mark region is irradiated with the beam.

14. The article manufacturing method according to claim 13,
wherein the position measurement device measures a position of the mark plural times, and
wherein the control unit corrects a position of the substrate relative to an irradiation position of the beam based on a result measured by the position measurement device.

15. The article manufacturing method according to claim 13, wherein the apparatus further comprises a plurality of position measurement devices, and wherein a position of the mark is measured plural times by the same position measurement device or different position measurement devices.

16. The apparatus according to claim 9,
wherein the position measurement device measures a position of the mark plural times, and
wherein the control unit corrects a position of the substrate relative to an irradiation position of the beam based on a result measured by the position measurement device.

17. The apparatus according to claim 9, further comprising a plurality of position measurement devices, wherein a position of the mark is measured plural times by the same position measurement device or different position measurement devices.

18. The method for the drawing data according to claim 2, wherein the predetermined timing is a timing after last position measurement with respect to the mark is completed.

19. The method for the drawing data according to claim 2, wherein the mark region is within a scribe line.

20. The method for the drawing data according to claim 2, wherein the mark region is a transition region of a unit irradiation region while the substrate is scanned in one direction with respect to the unit irradiation region of the beam.
